(19) United States
(12) Patent Application Publication
(10) Pub. No.: US 2023/0164973 A1
(43) Pub. Date: May 25, 2023

(54) SEMICONDUCTOR STRUCTURE AND MANUFACTURING METHOD THEREOF

(71) Applicant: CHANGXIN MEMORY TECHNOLOGIES, INC., Hefei City (CN)

(72) Inventor: Yutong SHEN, Hefei City (CN)

(21) Appl. No.: 18/152,202

(22) Filed: Jan. 10, 2023

Related U.S. Application Data
(63) Continuation of application No. PCT/CN2022/093364, filed on May 17, 2022.

(30) Foreign Application Priority Data
Aug. 27, 2021 (CN) 202110996603.1

(51) Int. Cl. H10B 12/00; H01L 21/04; H01L 21/768; H01L 21/311; H01L 29/423

(52) U.S. Cl. CPC H10B 12/053; H01L 21/0455; H01L 21/76885; H01L 21/31144; H01L 29/4236; H01L 29/0607

(57) ABSTRACT

A semiconductor structure and a manufacturing method are disclosed. The semiconductor structure includes: a substrate, including a core region and a peripheral region, where a part of the substrate of the core region is provided with a first gate, a first doped region is provided in a part of the substrate at two opposite sides of the first gate, and a dielectric layer is provided on the top surface of the first doped region; a part of the substrate of the peripheral region is provided with a second gate, and a second doped region is provided in a part of the substrate at two opposite sides of the second gate; a first conductive pillar; and a second conductive pillar, where a depth of the second conductive pillar into the second doped region is less than a depth of the first conductive pillar into the first doped region.

### CROSS-REFERENCE TO RELATED APPLICATIONS

This is a continuation of International Application No. PCT/CN2022/093364, filed on May 17, 2022, which claims the priority to Chinese Patent Application 202110996603.1, titled “SEMICONDUCTOR STRUCTURE AND MANUFACTURING METHOD THEREOF” and filed on Aug. 27, 2021. The entire contents of International Application No. PCT/CN2022/093364 and Chinese Patent Application 202110996603.1 are incorporated herein by reference.

### TECHNICAL FIELD

Embodiments of the present disclosure relate to, but are not limited to, a semiconductor structure and a manufacturing method thereof.

### BACKGROUND

With the continuous development of integrated circuit technology and process technology, to improve the integration degree of integrated circuits, the critical dimension of transistor (MOS) devices is continuously reduced. Under the process nodes such as the high-K material metal gate (HKMG) and the fin transistor (Finfet), a series of problems need to be resolved while the operation speed of the MOS device is increased and its power consumption is reduced.

### SUMMARY

An overview of the subject described in detail in the present disclosure is provided below. This overview is not intended to limit the protection scope of the claims.

According to some embodiments of the present disclosure, an aspect of the embodiments of the present disclosure provides a method of manufacturing a semiconductor structure, including: providing a substrate including a core region and a peripheral region, wherein the substrate is provided with gate structures in both the core region and the peripheral region, a first doped region is provided in a part of the substrate at two opposite sides of the gate structure of the core region, and a second doped region is provided in a part of the substrate at two opposite sides of the gate structure of the peripheral region; forming a barrier layer on a part of the substrate of the peripheral region, wherein the barrier layer is located on a surface of the second doped region; forming a mask layer with openings on a part of the substrate of the core region and the part of the substrate of the peripheral region, wherein the mask layer is further located on a surface of the barrier layer, and a material of the mask layer is different from a material of the barrier layer; etching a dielectric layer and the first doped region of the core region along one of the openings by using the mask layer as a mask, to form a first trench in the first doped region, and further etching the barrier layer and the second doped region of the peripheral region along one of the openings, to form a second trench in the second doped region, wherein a depth of the first trench is greater than a depth of the second trench; forming a first conductive pillar, wherein the first conductive pillar fills up the first trench and protrudes from a surface of the substrate; and forming a second conductive pillar, wherein the second conductive pillar fills up the second trench and protrudes from the surface of the substrate.

According to some embodiments of the present disclosure, another aspect of the embodiments of the present disclosure provides a semiconductor structure, including: a substrate, including a core region and a peripheral region, wherein the substrate is provided with gate structures in both the core region and the peripheral region, and a second doped region is provided in a part of the substrate at two opposite sides of the gate structure of the peripheral region; a first conductive pillar, wherein the first conductive pillar is located in the first doped region and protrudes from a surface of the substrate; and a second conductive pillar, wherein the second conductive pillar is located in the second doped region and protrudes from the surface of the substrate, and a depth of the second conductive pillar into the second doped region is less than a depth of the first conductive pillar into the first doped region.

Other aspects of the present disclosure are understandable upon reading and understanding of the accompanying drawings and detailed description.

### BRIEF DESCRIPTION OF THE DRAWINGS

The accompanying drawings incorporated into the specification and constituting a part of the specification illustrate the embodiments of the present disclosure, and are used together with the description to explain the principles of the embodiments of the present disclosure. In these accompanying drawings, similar reference numerals represent similar elements. The accompanying is drawings in the following description illustrate some rather than all of the embodiments of the present disclosure. Those skilled in the art may obtain other accompanying drawings based on these accompanying drawings without creative efforts.

FIG. 1 is a schematic structural diagram of a semiconductor structure;

FIG. 2 to FIG. 10 are schematic structural diagrams corresponding to a method of manufacturing a semiconductor structure according to an embodiment of the present disclosure;

FIG. 11 is another schematic structural diagram of a semiconductor structure according to an embodiment of the present disclosure; and

FIG. 12 to FIG. 20 are schematic structural diagrams corresponding to a method of manufacturing a semiconductor structure according to another embodiment of the present disclosure.

### DETAILED DESCRIPTION

The technical solutions in the embodiments of the present disclosure are described below clearly and completely with reference to the accompanying drawings in the embodiments of the present disclosure. Apparently, the described embodiments are merely some rather than all of the embodiments of the present disclosure. All other embodiments obtained by those skilled in the art based on the embodiments of the present disclosure without creative efforts should fall within the protection scope of the present disclosure. It should be noted that the embodiments in the present disclosure and features in the embodiments may be combined with each other in a non-conflicting manner.

At present, the junction depth of the source-drain region of the existing semiconductor structure decreases. However, an excessive depth of the contact via will lead to current leakage with the substrate.

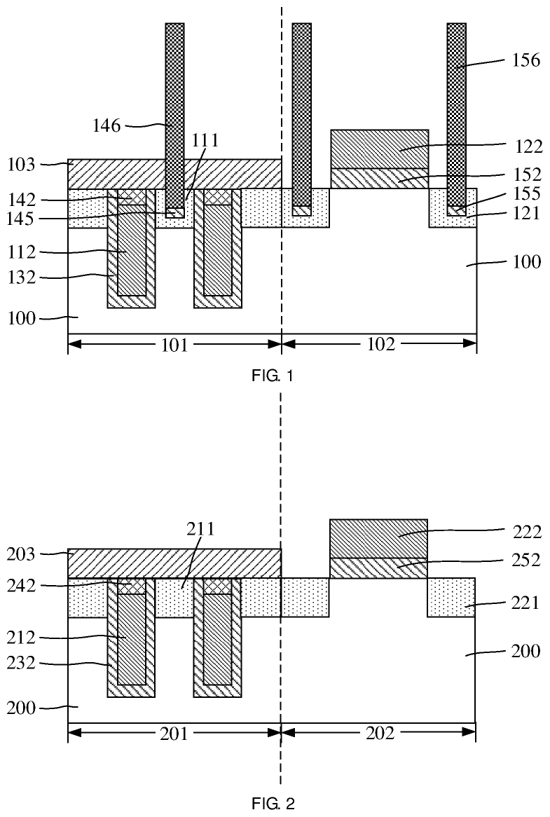

Upon analysis, the main reason of the foregoing problem is as follows: as the device size shrinks continuously, the distance between the conductive contact structure and the depletion zone of the source and drain becomes narrower, causing a leakage channel with the substrate. FIG. 1 is a schematic diagram of a semiconductor structure. Analysis is conducted with reference to FIG. 1. A substrate 100 includes a core region 101 and a peripheral region 102, where a first gate 112 is provided in the core region 101, a second gate 122 is provided on the peripheral region 102, a first doped region 111 is provided in the core region 101 at two opposite sides of the first gate 112, and a second doped region 121 is provided in the peripheral region 102 at two opposite sides of the second gate 122; a dielectric layer 103, located on a top surface of the core region 101; a first conductive pillar 146, where the first conductive pillar 146 is partially located in the first doped region 111 and partially protrudes from a surface of the substrate 100; and second conductive pillars 156, where the second conductive pillar 156 is partially located in the second doped region 121 and partially protrudes from the substrate 100. Moreover, due to the uniformity of the production processes, a depth of the second conductive pillar 156 into the second doped region 121 is the same as a depth of the first conductive pillar 146 into the dielectric layer 103. For a semiconductor PN junction, the difference in the original chemical potential of the semiconductor at two sides of an interface (a contact surface between the P-type semiconductor and the N-type semiconductor) causes an energy band near the interface to bend, and an interface zone where the carrier concentration in the bending region of the energy band decreases is a depletion zone. Due to the existence of the PN interface between the source-drain region and the substrate, the depth of the second conductive pillar 156 into the second doped region 121 is relatively large, and the distance between the second conductive pillar 156 and the depletion zone is small. Therefore, the contact leakage current between the conductive contact structure and the substrate of the semiconductor structure increases.

The doped region can be used as the source or drain of the semiconductor structure. The ion concentration in the doped region follows a Gaussian doping distribution, where the doped region closer to the surface of the substrate has lower doping concentration. The concentration of carriers in the semiconductor at two sides of the depletion zone differs significantly in the case of high doping concentration, and the diffusion motion of majority carriers is intense, which broadens a space charge region theoretically. However, the internal electric field generated in the space charge region causes the drift motion of minority carriers to be also intense, and the space charge region becomes narrower theoretically. Eventually, the diffusion motion rate of the majority carriers and the drift motion rate of the minority carriers reach dynamic equilibrium. It takes a shorter time for carriers to reach dynamic equilibrium in the case of high doping concentration than in the case of low doping concentration, and the width of the depletion zone is narrower due to a shorter electron-hole recombination time. When the depth of the second conductive pillar 156 into the second doped region 121 is relatively large, the two ends of the depletion zone are in the low doped region, and the formed depletion zone is relatively thick, which leads to a shorter distance between the second conductive pillar 156 and the depletion zone. The distance between the conductive pillar and the depletion zone is even shorter as the device size shrinks, and the contact leakage current between the conductive contact structure and the substrate of the semiconductor structure increases, which seriously affects the stability of the semiconductor structure.

Some embodiments of the present disclosure further provide a semiconductor structure and a manufacturing method thereof. The barrier layer located on the surface of the second doped region is formed on the part of the substrate of the peripheral region to adjust the etching depth, thereby increasing a distance between the bottom of the conductive contact structure and the PN junction that is formed between a source-drain terminal and the substrate, to alleviate the leakage between the conductive contact structure and the substrate of the semiconductor. The embodiments of the present disclosure reduce the depth of the second conductive pillar into the second doped region, such that the second conductive pillar is away from the depletion zone; in addition, the second doped region is doped with ions through preprocessing. Therefore, the contact resistance between the conductive contact structure and the semiconductor is relatively low, which helps improve the conductivity of the semiconductor structure. Moreover, the contact leakage current between the conductive contact structure and the substrate of the semiconductor structure is reduced, to help improve the stability of the semiconductor structure.

In order to make the objectives, technical solutions and advantages of the embodiments of the present disclosure clearer, the embodiments of the present disclosure are described below with reference to the accompanying drawings. However, those of ordinary skill in the art can understand that many technical details are proposed in the embodiments of the present disclosure to help readers better understand the present disclosure. However, even without these technical details and various changes and modifications made based on the following embodiments, the technical solutions claimed in the present disclosure may still be realized.

FIG. 2 to FIG. 10 are schematic structural diagrams corresponding to a method of manufacturing a semiconductor structure according to an embodiment of the present disclosure.

Referring to FIG. 2, a substrate 200 is provided. The substrate 200 includes a core region 201 and a peripheral region 202. A part of the substrate 200 of the core region 201 is provided with a first gate 212. A first doped region 211 is provided in a part of the substrate 200 at two opposite sides of the first gate 212 of the core region 201, and the substrate 200 exposes a top surface of the first doped region 211. A dielectric layer 203 is provided on the top surface of the first doped region 211. A part of the substrate 200 of the peripheral region 202 is provided with a second gate 222, and a second doped region 221 is provided in a part of the substrate 200 at two opposite sides of the second gate 222 of the peripheral region 202.

In some embodiments, the core region 201 is connected to a conductive structure to form a memory cell; the peripheral region 202 is connected to a conductive structure to form a logical unit, to ensure implementation of functions of the core region.

The substrate 200 is made of a semiconductor material. In some embodiments, the substrate 200 is made of silicon. In other embodiments, alternatively, the substrate may be made of germanium, silicon germanide, or silicon carbide.

In some embodiments, the first gate 212 in the core region 201 is a buried gate, and the second gate 222 in the peripheral region 202 is a planar gate.

The core region 201 further includes a first gate sidewall 232 and a first gate cover layer 242.

The first gate sidewall 232 covers a bottom wall and a side wall of the first gate 212, to block mutual diffusion of particles in the first gate 212 and particles in the first doped region 211. The first gate sidewall 232 is made of metal oxide, such as titanium nitride, tantalum nitride, titanium or tantalum.

The first gate cover layer 242 covers the surface of the first gate 212 to isolate the first gate 212 from the dielectric layer 203, where the first gate cover layer 242 is made of an insulating material, such as silicon dioxide, silicon carbide or silicon nitride. In some embodiments, the first gate 212 is made of tungsten. In other embodiments, the first gate may be made of another metal material such as copper or aluminum.

In some embodiments, the first gate 212 includes a first conductive layer of the first gate. In other embodiments, the first gate includes a first conductive layer of the first gate, a first gate dielectric layer, and a second conductive layer of the first gate that are sequentially stacked, and a material of the first conductive layer of the first gate may be different from a material of the second conductive layer of the first gate.

The peripheral region 202 further includes a second gate oxide layer 252 covering the substrate 200, and the second gate oxide layer 252 is located between the substrate 200 and the second gate 222.

The second gate oxide layer 252 is made of an insulating material, such as silicon dioxide, silicon carbide or silicon nitride, to isolate the second gate 222 from the substrate 200. In some embodiments, the material of the second gate oxide layer 252 may be the same as the material of the first gate cover layer 242. In other embodiments, the material of the second gate oxide layer may be different from the material of the first gate cover layer.

In some embodiments, the second gate 222 is made of tungsten. In other embodiments, the second gate 222 may be made of another metal material such as copper or aluminum. In some embodiments, the material of the first gate 212 is the same as the material of the second gate 222. In other embodiments, the material of the first gate may be different from the material of the second gate.

In some embodiments, the second gate 222 includes a first conductive layer of the second gate. In other embodiments, the second gate includes a first conductive layer of the second gate, a second gate dielectric layer, and a second conductive layer of the second gate that are sequentially stacked, and a material of the first conductive layer of the second gate may be different from a material of the second conductive layer of the second gate.

The first doped region 211 is an N-type doped region, and the second doped region 221 may be an N-type doped region or a P-type doped region. In some embodiments, the first doped region 211 and the second doped region 221 are N-type doped regions, and the substrate 200 is a P-type doped region. The first doped region 211 and the second doped region 221 are doped with N-type ions, and the substrate 200 is doped with P-type ions. In other embodiments, the doped regions are P-type doped region, and the substrate is an N-type doped region. The doped regions are doped with P-type ions, and the substrate is doped with N-type ions. The dopant ions in the second doped region 221 are boron ions in P-type ions. In other embodiments, the dopant ions may alternatively be phosphorus ions or arsenic ions in N-type ions, or aluminum ions or boron fluoride ions in P-type ions, and the like.

For the first gate 212, one part of the first doped region 211 at one side of the first gate 212 serves as the source, and the other part of the first doped region 211 at the other side of the first gate 212 serves as a drain. Similarly, for the second gate 222, one part of the second doped region 221 at one side of the second gate 222 serves as the source, and the other part of the second doped region 221 at the other side of the second gate 222 serves as the drain.

The dielectric layer 203 is located on the top surface of the first doped region 211. The dielectric layer 203 may be made of an insulating material such as silicon, silicon oxide, silicon carbide or silicon nitride, or other high-K materials. In some embodiments, the dielectric layer 203 covers the top surface of the first doped region 211, and also covers an upper surface of the first gate cover layer 242.

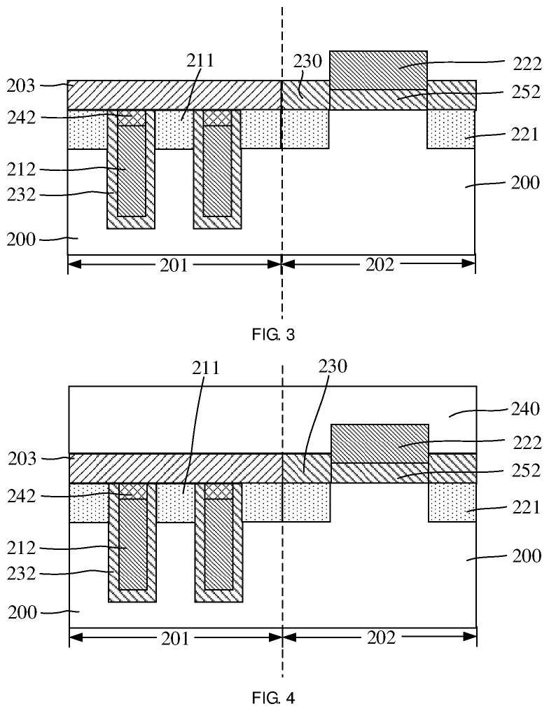

Referring to FIG. 3, a barrier layer 230 is formed on the part of the substrate 200 of the peripheral region 202. The barrier layer 230 is located on the surface of the second doped region 221.

The barrier layer 230 is also located on a side wall of the second gate 222 in the peripheral region 202, and a material of the barrier layer 230 is different from a material of the dielectric layer 203. In some embodiments, the material of the barrier layer 230 is silicon oxide. In other embodiments, the material of the barrier layer may be SiNₓ or C.

In the process of being etched with a same material, the barrier layer 230 is etched at a lower rate than the dielectric layer 203.

The barrier layer 230 is formed on the part of the substrate 200 of the peripheral region 202, where the barrier layer 230 is located on the surface of the second doped region 221. In the process of being etched with a same material, the barrier layer 230 is etched at a lower rate than the dielectric layer 203. In this case, there is a difference between the time for forming a via in the barrier layer 230 and the time for forming a via in the dielectric layer 203, such that in the process of forming a via in the dielectric layer 203, the second doped region 221 is partially etched, thereby increasing a distance between the bottom of the conductive contact structure subsequently formed in the trench of the second doped region 221 and the PN junction that uses the second doped region 221 as the source-drain terminal subsequently, thereby reducing the leakage current between the conductive contact structure and the substrate of the semiconductor structure.

In some embodiments of the present disclosure, the forming the barrier layer includes: forming an initial barrier film that is continuous on the surface of the substrate 200 of the core region 201 and the peripheral region 202, and then removing a part of the initial barrier film in the core region 201, where the remaining part of the initial barrier film serves as the barrier layer 230.

The surface of the formed barrier layer 230 is flush with the surface of the dielectric layer 203. In this way, the surface of the dielectric layer 203 on the substrate 200 and the surface of the barrier layer 230 on the substrate 200 form a flat surface, which simplifies the appearance of the semiconductor structure. While it is ensured that the surface of the dielectric layer 203 and the surface of the barrier layer 230 form a flat surface, the depth of the trench formed in the second doped region 221 depends on an etching selectivity between the dielectric layer 203 and the barrier layer 230, such that the depth of the trench formed in the second doped region 221 is controlled accurately, thereby accurately control the distance between the subsequently formed conductive contact structure and the PN junction.

In some embodiments, the initial barrier film is formed through atomic layer deposition. In other embodiments, the initial barrier film may be formed through chemical vapor deposition.

Referring to FIG. 4, a mask layer 240 is formed on the part of the substrate 200 of the core region 201 and the part of the substrate 200 of the peripheral region 202, and the mask layer 240 is further located on the surface of the barrier layer 230 and the surface of the dielectric layer 203. A material of the mask layer 240 is different from a material of the barrier layer 230.

Referring to FIG. 5, by using the mask layer 240 as a mask, the mask layer 240 is patterned to form openings, and then the dielectric layer 203 in the core region 201 is etched along one of the openings, to form a first trench 261 in the dielectric layer 203, where the first trench 261 exposes the top surface of the first doped region 211. In addition, the barrier layer 230 and part of the second doped region 221 in the peripheral region 202 are further etched along one of the openings, to form a second trench 262 in the barrier layer 230 and the second doped region 221, where a depth of the first trench 261 into the first doped region 211 is greater than a depth of the second trench 262 into the second doped region 221. In this way, the distance between the bottom of the second trench 262 (the bottom of the subsequently formed conductive contact structure) and the PN junction is further reduced, which helps reduce the contact leakage current between the subsequently formed conductive contact structure and the substrate of the semiconductor structure and helps improve the stability of the semiconductor structure.

In some embodiments, the mask layer 240 and the dielectric layer 203 are partially removed through wet etching, to form the first trench 261. In this case, the first trench 261 exposes the top surface of the first doped region 211, and the subsequently formed conductive pillar that fills up the first trench 261 can be in contact with a region with highest dopant ion concentration in the first doped region 211, which helps improve the contact performance between the metal and semiconductor. In other embodiments, alternatively, the mask layer and the dielectric layer may be partially removed through dry etching, to form the first trench. Similarly, in some embodiments, the mask layer 240, the barrier layer 230, and the second doped region 221 are partially removed to form the second trench 262. In this case, the second trench 262 exposes the side wall of the second doped region 221, and the subsequently formed conductive pillar that fills up the second trench 262 can be in contact with a region with highest dopant ion concentration in the second doped region 221, which helps improve the contact performance between the metal and the semiconductor. In other embodiments, alternatively, the mask layer, the barrier layer, and the second is doped region may be partially removed through dry etching, to form the second trench.

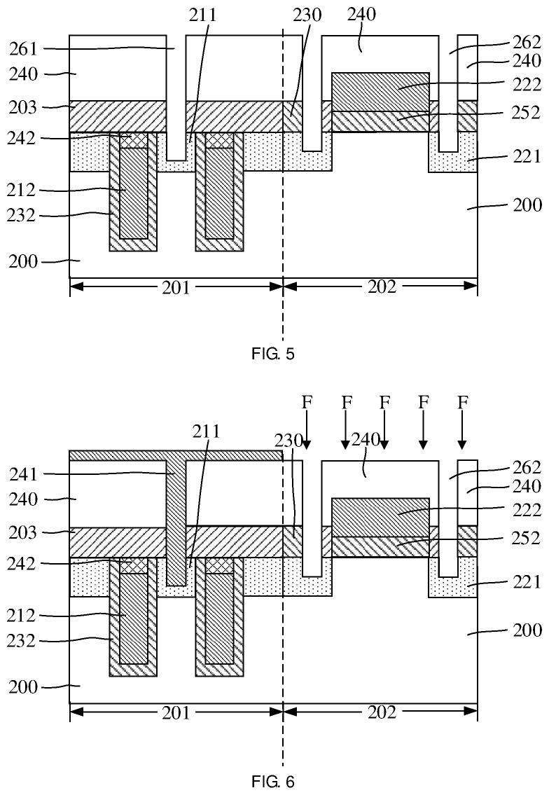

Referring to FIG. 6, a first mask layer 241 is formed on the part of the substrate 200 of the core region 201, and the second trench 262 is preprocessed, to improve the concentration of dopant ions in a part of the second doped region 221 exposed by the second trench 262; and the first mask layer 241 is removed after the preprocessing.

In some embodiments, the preprocessing includes: a first step preprocessing including doping the surface of the part of the second doped region 221 exposed by the second trench 262 with fluoride ions; and a second step preprocessing including doping the part of the surface of the second doped region 221 exposed by the second trench 262 with ions of a same type as the dopant ions in the second doped region 221. By doping with fluoride ions and implanting extra ions of the same type as the dopant ions in the second doped region, the concentration of dopant ions of the part of the second doped region exposed by the second trench is increased, thus reducing the contact resistance between the metal and the semiconductor.

In some embodiments, the dopant ions are boron ions and aluminum ions in P-type ions. In other embodiments, the dopant ions may be phosphorus ions, arsenic ions or the like in N-type ions.

In other embodiments, the first trench and the second trench are both preprocessed.

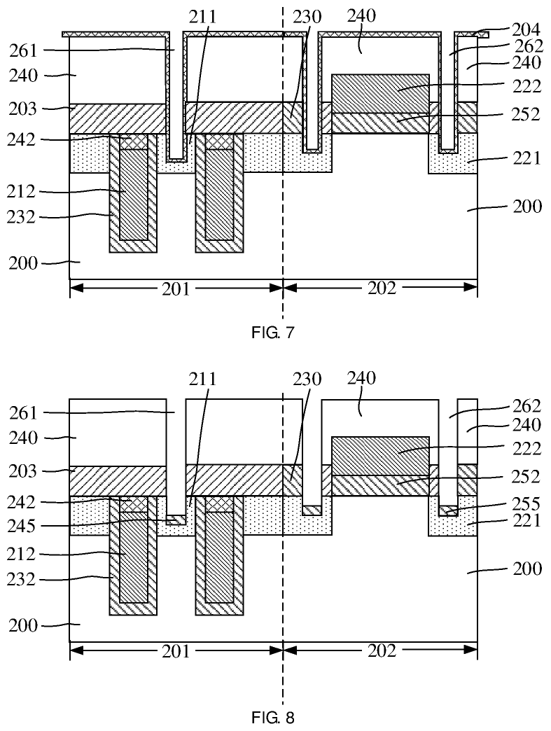

Referring to FIG. 7, a metal layer 204 is formed. The metal layer 204 is located on the surface of the first trench 261, the surface of the second trench 262, and the surface of the mask layer 240. In some embodiments, the metal layer 204 is made of cobalt. In other embodiments, the metal layer may be made of metal such as nickel or titanium.

In some embodiments, the metal layer 204 is formed through vacuum evaporation. In other embodiments, the metal layer may be formed through sputtering or vapor deposition.

In other embodiments, a metal layer is formed, where the metal layer is located only on the surface of the second trench and the surface of the mask layer right above the second trench.

Referring to FIG. 8, a first metal silicide layer 245 and a second metal silicide layer 255 are formed.

The forming the first metal silicide layer 245 and the second metal silicide layer 255 includes: performing an annealing process on the metal layer 204, such that a part of the metal layer 204 reacts with the first doped region 211 to form the first metal silicide layer 245, and a part of the metal layer 204 reacts with the second doped region 221 to form the second metal silicide layer 255; and removing a remaining part of the metal layer 204 that is unreacted.

In some embodiments, the first metal silicide layer 245 is made of cobalt silicide, to reduce resistance of a diffusion zone and contact resistance of a metal/conductor contact hole. In other embodiments, the first metal silicide layer may be made of metal silicide such as titanium silicide or nickel silicide. Similarly, in some embodiments, the second metal silicide layer 255 is made of cobalt silicide, to reduce the resistance of the diffusion zone and the contact resistance of the metal/conductor contact hole. In other embodiments, the second metal silicide layer may be made of metal silicide such as titanium silicide or nickel silicide.

In some embodiments, the material of the second metal silicide layer 255 is the same as the material of the first metal silicide layer 245. In other embodiments, the material of the second metal silicide layer may be different from the material of the first metal silicide layer.

In other embodiments, only the second metal silicide layer is formed.

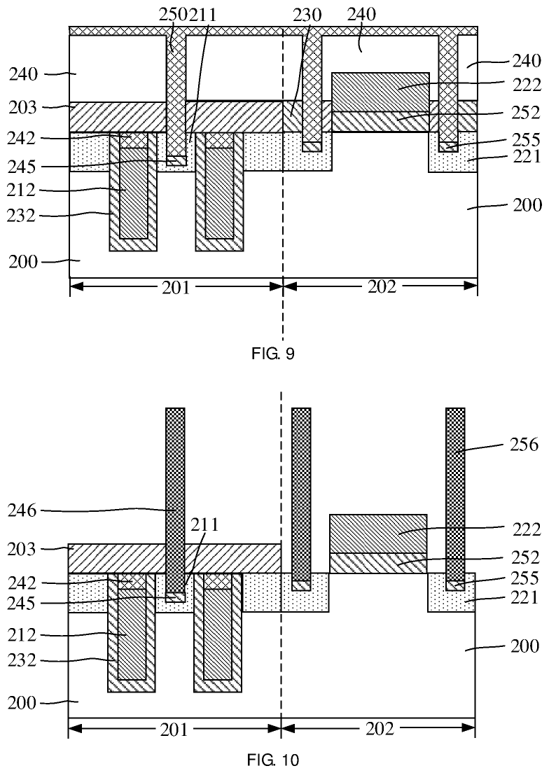

Referring to FIG. 9 and FIG. 10, a first conductive pillar 246 and a second conductive pillar 256 are formed. The first conductive pillar 246 fills up the first trench 261 and protrudes from the surface of the substrate 200. The second conductive pillar 256 fills up the second trench 262 and protrudes from the surface of the substrate 200.

The forming the first conductive pillar 246 and the second conductive pillar 256 includes: forming a conductive film 250 that fills up the first trench 261, the second trench 262 and the openings, where the conductive film 250 is further located on the top surface of the mask layer 240; removing a part of the conductive film 250 that is higher than the top surface of the mask layer 240, where the remaining part of the conductive film 250 in the core region 201 serves as the first conductive pillar 246, and the remaining part of the conductive film 250 in the peripheral region 202 serves as the second conductive pillar 256; and removing the mask layer 240.

Referring to FIG. 9, the conductive film 250 that fills up the first trench 261, the second trenches 262 and the openings is formed, where the conductive film 250 is further located on the top surface of the mask layer 240.

In some embodiments, the conductive film 250 is made of tungsten. In other embodiments, the conductive film may be made of metal such as silver.

Referring to FIG. 10, a part of the conductive film 250 that is higher than the top surface of the mask layer 240 is removed, where the remaining part of the conductive film 250 in the core region 201 serves as the first conductive pillar 246, and the remaining part of the conductive film 250 in the peripheral region 202 serves as the second conductive pillar 256; the mask layer is removed.

It should be noted that, in some embodiments, the first metal silicide layer 245 is located on a bottom surface of the first trench 261 and is located between the first conductive pillar 246 and the first doped region 211; the second metal silicide layer 255 is located on a bottom surface of the second trench 262, and is located between the second conductive pillar 256 and the second doped region 221.

The first metal silicide layer 245 and the second metal silicide layer 255 have relatively low contact resistance, which helps improve the conductive effect between the conductive contact structure and the second doped region 221.

In some embodiments, the second metal silicide layer 255 is located on the bottom surface of the second trench and the side wall of the second doped region 221 to form a groove. In this case, the second metal silicide layer 255 and the second doped region 221 have a relatively large contact area. As the contact area expands, the contact resistance between the second metal silicide layer 255 and the second doped region 221 is reduced, which helps improve the conductive effect between the second metal silicide layer 255 and the second doped region 221, thereby improving the performance of the semiconductor structure.

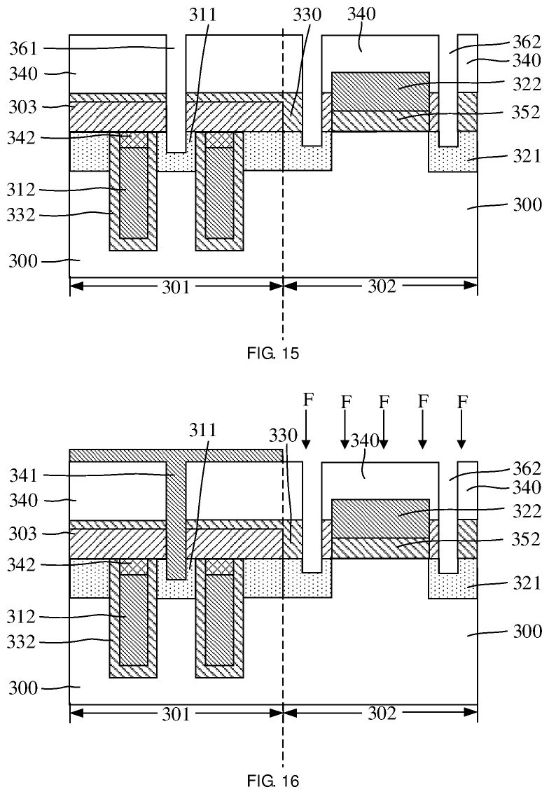

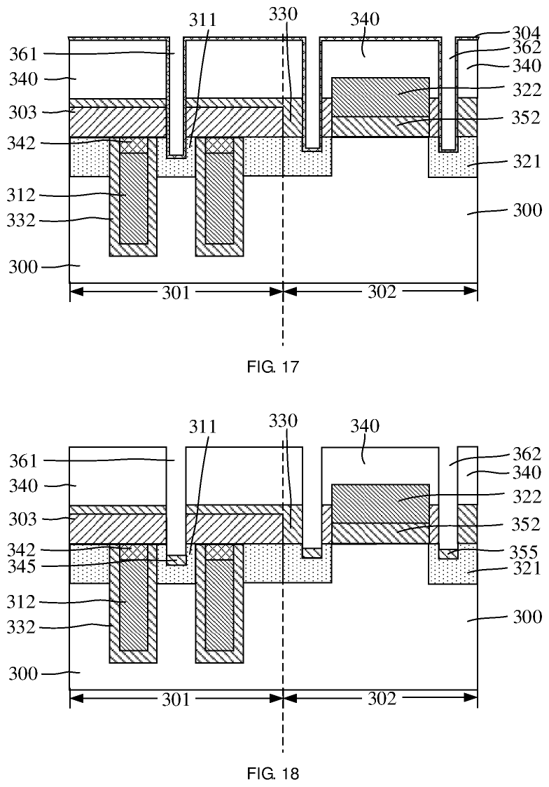

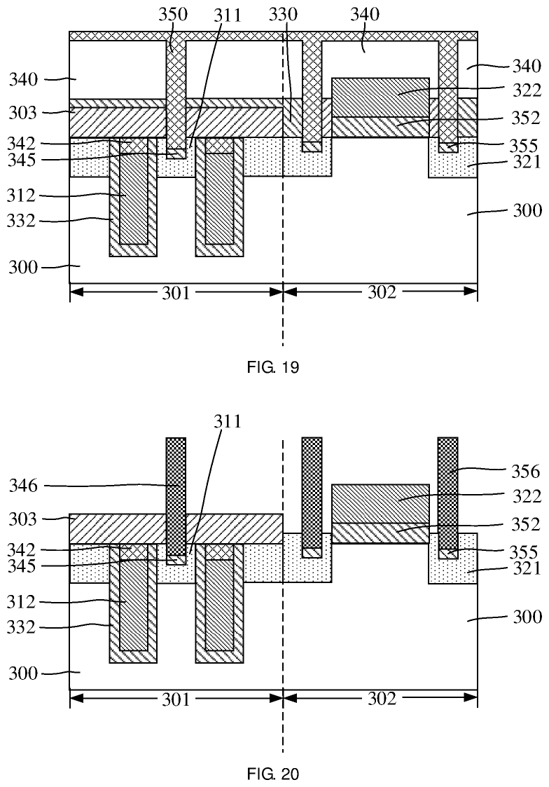

In some embodiments, the barrier layer is formed on the part of the substrate of the peripheral region, and the barrier layer is located on the surface of the second doped region. The etching depth is adjusted based on etching rates of different materials, thereby increasing the distance between the bottom of the conductive contact structure and the PN junction that is formed between the source-drain terminal and the substrate, thus adjusting the contact leakage current between the conductive contact structure and the substrate of the semiconductor structure. Some embodiments of the present disclosure reduce the depth of the second conductive pillar into the second doped region, such that the second conductive pillar is away from the depletion zone, which helps alleviate the excessive leakage current in the substrate of the semiconductor structure, thereby improving the stability of the semiconductor structure. In addition, the first conductive pillar is located in the first doped region and protrudes from the surface of the substrate; the second conductive pillar is located in the second doped region and protrudes from the surface of the substrate; besides, the depth of the second conductive pillar into the second doped region is less than the depth of the first conductive pillar into the first doped region. On one hand, the depth of the first conductive pillar into the first doped region ensures good conductivity between the core region and the conductive pillar; on the other hand, it avoids excessive leakage current of the substrate of the semiconductor structure caused by an extremely large depth is of the second conductive pillar into the second doped region. FIG. 12 to FIG. 20 are schematic structural diagrams corresponding to a method of manufacturing a semiconductor structure according to another embodiment of the present disclosure.

Referring to FIG. 12, a substrate 300 is provided. The substrate 300 includes a core region 301 and a peripheral region 302. A part of the substrate 300 of the core region 301 is provided with a first gate 312. A first doped region 311 is provided in a part of the substrate 300 at two opposite sides of the first gate 312 of the core region 301, and the substrate 300 exposes a top surface of the first doped region 311. A dielectric layer 303 is provided on the top surface of the first doped region 311. A part of the substrate 300 of the peripheral region 302 is provided with a second gate 322, and a second doped region 321 is provided in a part of the substrate 300 at two opposite sides of the second gate 322 of the peripheral region 302.

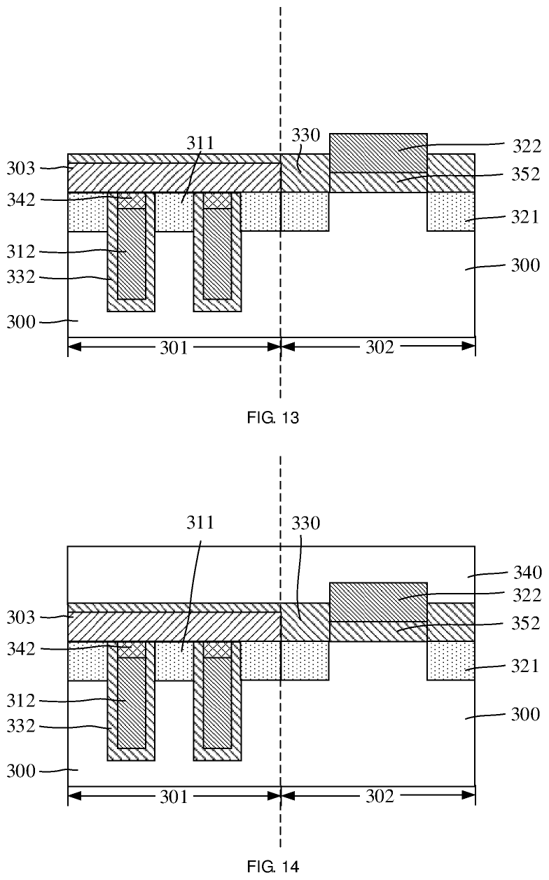

Referring to FIG. 13, a barrier layer is deposited on the substrate 300 of the peripheral region 302 and the core region 301, and then a barrier layer 330 with a preset thickness is formed through chemical mechanical polishing or etching. The barrier layer 330 is located on a surface of the second doped region 321 and a surface of the dielectric layer 303.

In a direction perpendicular to the substrate 300, the barrier layer 330 has a thickness of 5 nm-20 nm. It is found that, at the thickness of 5 nm-20 nm, an etching depth of the second conductive pillar in the second doped region is less than an etching depth of the first conductive pillar in the first doped region.

The part of the method of manufacturing a semiconductor structure corresponding to FIG. 14 to FIG. 20 are the same as the part of the method of manufacturing a semiconductor structure corresponding to FIG. 4 to FIG. 10, and details are not described again.

In some embodiments, the barrier layer is formed on the substrate of the peripheral region and the core region, where the barrier layer is located on the surface of the second doped region and the surface of the dielectric layer. On is the one hand, by adjusting the thickness of a part of the barrier layer on the surface of the dielectric layer, the depth of the first conductive pillar into the first doped region is adjusted, to ensure good conductivity between the first conductive pillar and the first doped region. On the other hand, by adjusting the thickness of a part of the barrier layer on the surface of the second doped region, it is ensured that the etching depth of the second doped region is less than the etching depth of the first doped region by using etching rates of different materials, such that the second conductive pillar is away from the depletion zone, which helps alleviate the excessive leakage current in the substrate of the semiconductor structure, thereby improving the stability of the semiconductor structure.

Some embodiments of the present disclosure provide a method of manufacturing a semiconductor structure, which can be used to manufacture a semiconductor structure provided by the following embodiments. The semiconductor structure provided by some embodiments of the present disclosure will be described below in detail with reference to the accompanying drawings.

FIG. 10 is a schematic structural diagram of a semiconductor structure according to an embodiment of the present disclosure.

Referring to FIG. 10, the semiconductor structure includes: a substrate 200 including a core region 201 and a peripheral region 202. A part of the substrate 200 of the core region 201 is provided with a first gate 212, and a first doped region 211 is provided in a part of the substrate 200 at two opposite sides of the first gate of the core region 201. The substrate 200 exposes a top surface of the first doped region 211, and a dielectric layer 203 is provided on the top surface of the first doped region 211. A part of the substrate 200 of the peripheral region 202 is provided with a second gate 222, and a second doped region 221 is provided in a part of the substrate 200 at two opposite sides of the second gate 222 of the peripheral region 202. A first conductive pillar 246 is located in the first doped region 211 and protrudes from a surface of the substrate 200. A second conductive pillar 256 is located in the second doped region 221 and protrudes from the surface of the substrate 200. A depth of the second conductive pillar 256 into the second doped region 221 is less than a depth of the first doped region 211 into the first conductive pillar 246.

In some embodiments, the core region 201 is connected to a conductive structure to form a memory cell; the peripheral region 202 is connected to a conductive structure to form a logical unit, to ensure implementation of functions of the core region.

The substrate 200 is made of a semiconductor material. Specifically, in some embodiments, the substrate 200 is made of silicon. In other embodiments, alternatively, the substrate may be made of germanium, silicon germanide, or silicon carbide.

In some embodiments, the first gate 212 in the core region 201 is a buried gate, and the second gate 222 in the peripheral region 202 is a planar gate.

The core region 101 further includes a first gate sidewall 232 and a first gate cover layer 242.

The first gate sidewall 232 covers a bottom wall and a side wall of the first gate 212, to block mutual diffusion of particles in the first gate 212 and particles in the first doped region 211. The first gate sidewall 232 is made of metal oxide, such as titanium nitride, tantalum nitride, titanium or tantalum.

The first gate cover layer 242 covers the surface of the first gate 212 to isolate the first gate 212 from the dielectric layer 203, where the first gate cover layer 242 is made of an insulating material, such as silicon dioxide, silicon carbide or silicon nitride. In some embodiments, the first gate 212 is made of tungsten. In other embodiments, the first gate may be made of another metal material such as copper or aluminum.

In some embodiments, the first gate 212 includes a first conductive layer of the first gate. In other embodiments, the first gate includes a first conductive layer of the first gate, a first gate dielectric layer, and a second conductive layer of the first gate that are sequentially stacked, and a material of the first conductive layer of the first gate may be different from a material of the second conductive layer of the first gate.

The peripheral region 202 further includes a second gate oxide layer 252 covering the substrate 200, and the second gate oxide layer 252 is located between the substrate 200 and the second gate 222.

The second gate oxide layer 252 is made of an insulating material, such as silicon dioxide, silicon carbide or silicon nitride, to isolate the second gate 222 from the substrate 200. In some embodiments, the material of the second gate oxide layer 252 may be the same as the material of the first gate cover layer 242. In other embodiments, the material of the second gate oxide layer may be different from the material of the first gate cover layer.

In some embodiments, the second gate 222 is made of tungsten. In other embodiments, the second gate 222 may be made of another metal material such as copper or aluminum. In some embodiments, the material of the first gate 212 is the same as the material of the second gate 222. In other embodiments, the material of the first gate may be different from the material of the second gate.

In some embodiments, the second gate 222 includes a first conductive layer of the second gate. In other embodiments, the second gate includes a first conductive layer of the second gate, a second gate dielectric layer, and a second conductive layer of the second gate that are sequentially stacked, and a material of the first conductive layer of the second gate may be different from a material of the second conductive layer of the second gate.

The first doped region 211 is an N-type doped region, and the second doped region 221 may be an N-type doped region or a P-type doped region. In some embodiments, the first doped region 211 and the second doped region 221 are N-type doped regions, and the substrate 200 is a P-type doped region. The first doped region 211 and the second doped region 221 are doped with N-type ions, and the substrate 200 is doped with P-type ions. In other embodiments, the doped regions are P-type doped region, and the substrate is an N-type doped region. The doped regions are doped with P-type ions, and the substrate is doped with N-type ions. The dopant ions in the second doped region 221 are boron ions in P-type ions. In other embodiments, the dopant ions may alternatively be phosphorus ions or arsenic ions in N-type ions, or aluminum ions or boron fluoride ions in P-type ions, and the like.

For the first gate 212, one part of the first doped region 211 at one side of the first gate 212 serves as the source, and the other part of the first doped region 211 at the other side of the first gate 212 serves as a drain. Similarly, for the second gate 222, one part of the second doped region 221 at one side of the second gate 222 serves as the source, and the other part of the second doped region 221 at the other side of the second gate 222 serves as the drain.

The dielectric layer 203 is located on the top surface of the first doped region 211. The dielectric layer 203 may be made of an insulating material such as silicon, silicon oxide, silicon carbide or silicon nitride, or other high-K materials. In some embodiments, the dielectric layer 203 covers the top surface of the first doped region 211, and also covers an upper surface of the first gate cover layer 242.

The first conductive pillar 246 is located in the first doped region 211 and protrudes from the surface of the substrate 200, which helps achieve good conductivity between the core region and the conductive pillar.

In some embodiments, the second conductive pillar 256 and the first conductive pillar 246 are made of a same material. In other embodiments, the second conductive pillar and the first conductive pillar may be made of different materials.

The second conductive pillar 256 is located in the second doped region 221 and protrudes from the surface of the substrate 200. The depth of the second conductive pillar 256 into the second doped region 221 is less than the depth of the first conductive pillar 246 into the dielectric layer 203.

In this way, a distance between the second conductive pillar 256 and a depletion zone of a PN junction in the second doped region 221 is increased. Under the effect of the concentration of dopant ions, the depletion zone of the PN junction becomes narrower, which helps prepare good ohmic contact by using dopant ions with high concentration in the metal-semiconductor contact area, thereby effectively avoiding excessively high contact resistance between the conductive contact structure and the semiconductor and improving the stability of the semiconductor structure.

The first metal silicide layer 245 is located between the first conductive pillar 246 and the first doped region 211. The second metal silicide layer 255 is located between the second conductive pillar 256 and the second doped region 221, and the second metal silicide layer 255 is located at a bottom surface of the second conductive pillar 256.

In some embodiments, the first metal silicide layer 245 is made of cobalt silicide to reduce the resistance of a diffusion zone and contact resistance of a metal/conductor contact hole. In other embodiments, the first metal silicide layer may be made of metal silicide such as titanium silicide or nickel silicide. Similarly, in some embodiments, the second metal silicide layer 255 and the first metal silicide layer 245 are made of a same material. In other embodiments, the second metal silicide layer and the first metal silicide layer may be made of different materials. Therefore, the second metal silicide layer has lower contact resistance, which helps improve a conductive effect between the second conductive pillar and the second doped region.

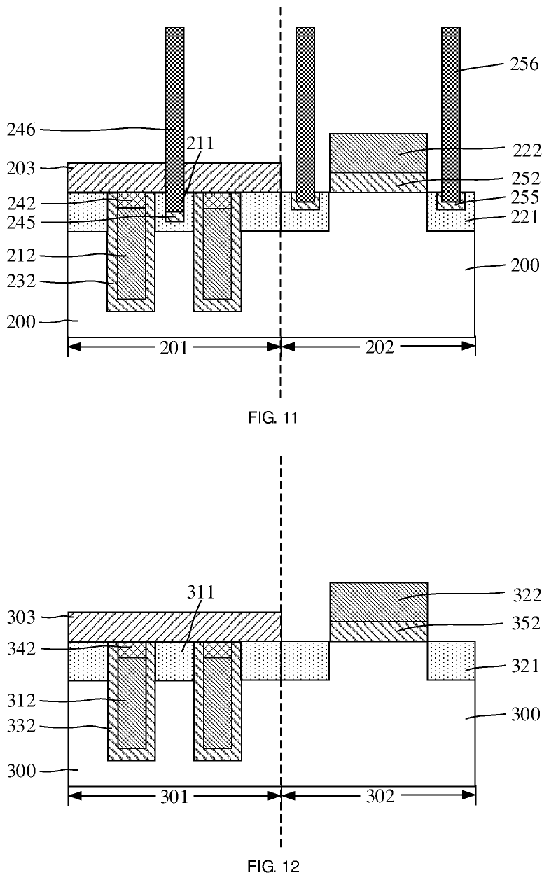

FIG. 11 is another schematic structural diagram of a semiconductor structure according to an embodiment of the present disclosure.

Referring to FIG. 11, in other embodiments, the second metal silicide layer is located on a bottom surface and a side surface of the second conductive pillar. Therefore, the second metal silicide layer and the second doped region have a relatively large contact area. As the contact area expands, the contact resistance between the second metal silicide layer and the second doped region is reduced, which helps improve the conductive effect between the second metal silicide layer and the second doped region, thereby improving the stability of the semiconductor structure.

Further referring to FIG. 10, the second metal silicide layer 255 is further provided with fluoride ions therein. By doping with fluoride ions and implanting extra ions of the same type as the dopant ions in the second doped region, the concentration of dopant ions of the part of the second doped region exposed by the second trench is increased, thus reducing the contact resistance between the metal and the semiconductor.

Another embodiment of the present disclosure further provides a semiconductor structure. The semiconductor structure provided by another embodiment of the present disclosure is substantially the same as the semiconductor structure provided by the foregoing embodiment, except that the depth of the first conductive pillar into the first doped region of the semiconductor structure provided by another embodiment of the present disclosure is less than the depth of the first conductive pillar into the first doped region of the semiconductor structure provided by the foregoing embodiment, and the depth of the second conductive pillar into the second doped region of the semiconductor structure provided by another embodiment of the present disclosure is also less than the depth of the second conductive pillar into the second doped region of the semiconductor structure provided by the foregoing embodiment. The semiconductor structure provided by another embodiment of the present disclosure is described in detail below with reference to the accompanying drawings.

FIG. 20 is a schematic structural diagram of a semiconductor structure according to another embodiment of the present disclosure.

Referring to FIG. 20, the semiconductor structure includes: a substrate 300, including a core region 301 and a peripheral region 302, where a part of the substrate 300 of the core region 301 is provided with a first gate 312, and a first doped region 311 is provided in a part of the substrate 300 at two opposite sides of the first gate 312 of the core region 301. The substrate 300 exposes a top surface of the first doped region 311, and a dielectric layer 303 is provided on is the top surface of the first doped region 311. A part of the substrate 300 of the peripheral region 302 is provided with a second gate 322, and a second doped region 321 is provided in a part of the substrate 300 at two opposite sides of the second gate 322 of the peripheral region 302. A first conductive pillar 346 is located in the first doped region 311 and protrudes from a surface of the substrate 300. A second conductive pillar 356 is located in the second doped region 321 and protrudes from the surface of the substrate 300. A depth of the second conductive pillar 356 into the second doped region 321 is less than a depth of the first conductive pillar 346 into the first doped region 311.

The semiconductor structure provided by another embodiment of the present disclosure is substantially the same as the semiconductor structure provided by the foregoing embodiment, and details are not described again herein.

The embodiments or implementations of this specification are described in a progressive manner, and each embodiment focuses on differences from other embodiments. The same or similar parts between the embodiments may refer to each other.

In the description of this specification, the description with reference to terms such as “an embodiment”, “an exemplary embodiment”, “some implementations”, “a schematic implementation”, and “an example” means that the specific feature, structure, material, or characteristic described in combination with the implementation(s) or example(s) is included in at least one implementation or example of the present disclosure.

In this specification, the schematic expression of the above terms does not necessarily refer to the same implementation or example. Moreover, the described specific feature, structure, material or characteristic may be combined in an appropriate manner in any one or more implementations or examples.

It should be noted that in the description of the present disclosure, the terms such as “center”, “top”, “bottom”, “left”, “right”, “vertical”, “horizontal”, “inner” and “outer” indicate the orientation or position relationships based on the accompanying drawings. These terms are merely intended to facilitate description of the present disclosure and simplify the description, rather than to indicate or imply that the mentioned apparatus or element must have a specific orientation and must be constructed and operated in a specific orientation. Therefore, these terms should not be construed as a limitation to the present disclosure.

It can be understood that the terms such as “first” and “second” used in the present disclosure can be used to describe various structures, but these structures are not limited by these terms. Instead, these terms are merely intended to distinguish one structure from another.

The same elements in one or more accompanying drawings are denoted by similar reference numerals. For the sake of clarity, various parts in the accompanying drawings are not drawn to scale. In addition, some well-known parts may not be shown. For the sake of brevity, a structure obtained by implementing a plurality of steps may be shown in one figure. In order to understand the present disclosure more clearly, many specific details of the present disclosure, such as the structure, material, size, processing process, and technology of the device, are described below. However, as those skilled in the art can understand, the present disclosure may not be implemented according to these specific details.

Finally, it should be noted that the above embodiments are merely intended to explain the technical solutions of the present disclosure, rather than to limit the present disclosure. Although the present disclosure is described in detail with reference to the above embodiments, those skilled in the art should understand that they may still modify the technical solutions described in the above embodiments, or make equivalent substitutions of some or all of the technical features recorded therein, without deviating the essence of the corresponding technical solutions from the scope of the technical solutions of the embodiments of the present disclosure.

### INDUSTRIAL APPLICABILITY

The semiconductor structure and the manufacturing method thereof provided by the embodiments of the present disclosure can solve the problem of high leakage current of the substrate due to an excessively deep contact via as the junction depth of the existing semiconductor structure decreases, thereby improving the stability of the semiconductor structure.

1. A method of manufacturing a semiconductor structure, comprising:
providing a substrate comprising a core region and a peripheral region, wherein a part of the substrate of the core region is provided with a first gate, a first doped region is provided in a part of the substrate at two opposite sides of the first gate of the core region, the substrate exposes a top surface of the first doped region, and a dielectric layer is provided on the top surface of the first doped region; a part of the substrate of the peripheral region is provided with a second gate, and a second doped region is provided in a part of the substrate at two opposite sides of the second gate of the peripheral region;
forming a barrier layer on the part of the substrate of the peripheral region, wherein the barrier layer is located on a surface of the second doped region;
forming a mask layer with openings on the part of the substrate of the core region and the part of the substrate of the peripheral region, wherein the mask layer is further located on a surface of the barrier layer and a surface of the dielectric layer, and a material of the mask layer is different from a material of the barrier layer;
etching the dielectric layer and the first doped region of the core region along one of the openings by using the mask layer as a mask, to form a first trench in the first doped region, and further etching the barrier layer and the second doped region of the peripheral region along one of the openings, to form a second trench in the second doped region, wherein a depth of the first trench is greater than a depth of the second trench;
forming a first conductive pillar, wherein the first conductive pillar fills up the first trench and protrudes from a surface of the substrate; and
forming a second conductive pillar, wherein the second conductive pillar fills up the second trench and protrudes from the surface of the substrate.

2. The method of manufacturing a semiconductor structure according to claim 1, wherein the barrier layer is further located on a side wall of the second gate of the peripheral region.

3. The method of manufacturing a semiconductor structure according to claim 1, wherein the material of the barrier layer comprises silicon oxide or silicon nitride.

4. The method of manufacturing a semiconductor structure according to claim 1, wherein the forming a barrier layer comprises:
forming an initial barrier film that is continuous on the surface of the substrate of the core region and the peripheral region; and
removing a part of the initial barrier film located in the core region, wherein a remaining part of the initial barrier film serves as the barrier layer.

5. The method of manufacturing a semiconductor structure according to claim 1, wherein the second doped region has dopant ions, the dopant ions are N-type ions or P-type ions, and the method of manufacturing further comprises:
preprocessing the second trench, to improve a concentration of the dopant ions in a part of the second doped region exposed by the second trench.

6. The method of manufacturing a semiconductor structure according to claim 5, wherein the preprocessing comprises: a first step preprocessing comprising doping a surface of the part of the second doped region exposed by the second trench with fluoride ions; and a second step preprocessing comprising doping the surface of the part of the second doped region exposed by the second trench with ions of a same type as the dopant ions in the second doped region, wherein the ions of the same type as the dopant ions in the second doped region are the N-type ions or the P-type ions.

7. The method of manufacturing a semiconductor structure according to claim 6, wherein the dopant ions are the P-type ions, and the ions of the same type as the dopant ions comprise boron fluoride ions.

8. The method of manufacturing a semiconductor structure according to claim 1, before the forming a first conductive pillar and the forming a second conductive pillar, the method further comprises:
forming a first metal silicide layer on a surface of the first trench, wherein the first metal silicide layer is located between the first conductive pillar and the first doped region; and
forming a second metal silicide layer on a surface of the second trench, wherein the second metal silicide layer is located between the second conductive pillar and the second doped region.

9. The method of manufacturing a semiconductor structure according to claim 8, wherein the forming a first metal silicide layer and the forming a second metal silicide layer comprise:
forming a metal layer, wherein the metal layer is located on the surface of the first trench, the surface of the second trench, and a surface of the barrier layer right above the second trench;
performing an annealing process, wherein a part of the metal layer reacts with the first doped region to form the first metal silicide layer, and a part of the metal layer reacts with the second doped region to form the second metal silicide layer; and
removing a remaining part of the metal layer that is unreacted.

10. The method of manufacturing a semiconductor structure according to claim 1, wherein the forming a first conductive pillar and the forming a second conductive pillar comprise:
forming a conductive film that fills up the first trench, the second trench and the openings, wherein the conductive film is further located on a top surface of the mask layer; and
removing a part of the conductive film that is higher than the top surface of the mask layer, wherein a remaining part of the conductive film located in the core region serves as the first conductive pillar, and a remaining part of the conductive film located in the peripheral region serves as the second conductive pillar.

11. The method of manufacturing a semiconductor structure according to claim 1, after the forming a first conductive pillar and the forming a second conductive pillar, the method further comprises: removing the mask layer.

12. A semiconductor structure, comprising:
a substrate, comprising a core region and a peripheral region, wherein a part of the substrate of the core region is provided with a first gate, a first doped region is provided in a part of the substrate at two opposite sides of the first gate of the core region, the substrate exposes a top surface of the first doped region, and a dielectric layer is provided on the top surface of the first doped region; a part of the substrate of the peripheral region is provided with a second gate, and a second doped region is provided in a part of the substrate at two opposite sides of the second gate of the peripheral region;
a first conductive pillar, wherein the first conductive pillar is located in the first doped region and protrudes from a surface of the substrate; and
a second conductive pillar, wherein the second conductive pillar is located in the second doped region and protrudes from the surface of the substrate, and a depth of the second conductive pillar into the second doped region is less than a depth of the first conductive pillar into the first doped region.

13. The semiconductor structure according to claim 12, further comprising:
a first metal silicide layer, located between the first conductive pillar and the first doped region; and
a second metal silicide layer, located between the second conductive pillar and the second doped region.

14. The semiconductor structure according to claim 13, wherein the second metal silicide layer is located on a bottom surface of the second conductive pillar.

15. The semiconductor structure according to claim 14, wherein the second metal silicide layer is further located on a side surface of the second conductive pillar.

16. The semiconductor structure according to claim 13, wherein the second metal silicide layer is further provided with fluoride ions therein.
